(19) United States
(12) Patent Application Publication
(10) Pub. No.: US 2025/0331260 A1
(43) Pub. Date: Oct. 23, 2025

(54) SEMICONDUCTOR DEVICE AND WAFER

(71) Applicant: KABUSHIKI KAISHA TOSHIBA, Tokyo (JP)

(72) Inventors: Ryoma KANEKO, Ota (JP); Seiya TAKEDA, Yokohama (JP); Jumpei TAJIMA, Mitaka (JP); Shinya NUNOUE, Ichikawa (JP); Toshiki HIKOSAKA, Kawasaki (JP)

(73) Assignee: KABUSHIKI KAISHA TOSHIBA, Tokyo (JP)

(21) Appl. No.: 19/018,377

(22) Filed: Jan. 13, 2025

(30) Foreign Application Priority Data
Apr. 17, 2024 (JP) 2024-066941

(51) Int. Cl. H10D 62/60; H10D 8/50; H10D 62/85

(52) U.S. Cl. CPC H10D 62/60; H10D 8/50; H10D 62/8503

(57) ABSTRACT

According to one embodiment, a semiconductor device includes first and second nitride regions, and first and second electrodes. Thea first nitride region includes a first region and a second region. The first region includes Alₓ₁Ga₁₋ₓ₁N (0<x1≤1). The second region includes Alₓ₂Ga₁₋ₓ₂N (0≤x2<x1). The second nitride region includes Al_{y2}Ga_{1-y2}N (0<y2≤1). The second region is between the first region and the second nitride region. A composition ratio x1 decreases along a first direction from the first region to the second nitride region. A composition ratio x2 decreases along the first direction. A first change rate of the composition ratio x1 with respect to a change in a position along the first direction is higher than a second change rate of the composition ratio x2 with respect to the change in the position along the first direction.

### CROSS-REFERENCE TO RELATED APPLICATIONS

This application is based upon and claims the benefit of priority from Japanese Patent Application No. 2024-066941, filed on Apr. 17, 2024; the entire contents of which are incorporated herein by reference.

### FIELD

Embodiments described herein relate generally to a semiconductor device and a wafer.

### BACKGROUND

For example, it is desired to improve the characteristics of semiconductor devices.

### BRIEF DESCRIPTION OF THE DRAWINGS

FIG. 1 is a schematic cross-sectional view illustrating a semiconductor device according to a first embodiment;

FIG. 2 is a graph illustrating the semiconductor device according to the first embodiment;

FIG. 3 is a schematic cross-sectional view illustrating a semiconductor device according to the first embodiment;

FIG. 4 is a schematic cross-sectional view illustrating a semiconductor device according to the first embodiment; and

FIG. 5 is a schematic cross-sectional view illustrating a wafer according to a second embodiment.

### DETAILED DESCRIPTION

According to one embodiment, a semiconductor device includes a first nitride region, a second nitride region, a first electrode, and a second electrode. The first nitride region includes a first region and a second region. The first region includes Alₓ₁Ga₁₋ₓ₁N (0<x1≤1). The second region includes Alₓ₂Ga₁₋ₓ₂N (0≤x2<x1). The second nitride region includes Al_{y2}Ga_{1-y2}N (0<y2≤1). The second region is between the first region and the second nitride region. The first electrode is electrically connected to the first region. The second electrode is electrically connected to the second nitride region. A composition ratio x1 decreases along a first direction from the first region to the second nitride region. A composition ratio x2 decreases along the first direction. A first change rate of the composition ratio x1 with respect to a change in a position along the first direction is higher than a second change rate of the composition ratio x2 with respect to the change in the position along the first direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

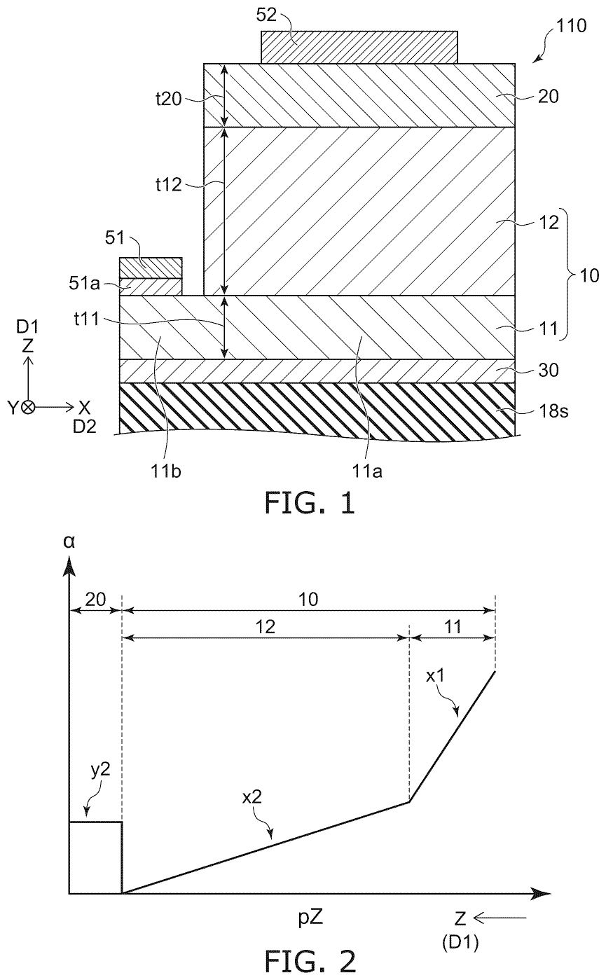

FIG. 1 is a schematic cross-sectional view illustrating a semiconductor device according to a first embodiment.

FIG. 2 is a graph illustrating the semiconductor device according to the first embodiment.

As shown in FIG. 1, a semiconductor device 110 according to the embodiment includes a first nitride region 10, a second nitride region 20, a first electrode 51, and a second electrode 52. The first nitride region 10 includes a first region 11 and a second region 12. The first region 11 includes Alₓ₁Ga₁₋ₓ₁N (0<x1≤1). The second region 12 includes Alₓ₂Ga₁₋ₓ₂N (0≤x2<x1). The first region 11 and the second region 12 may include crystals.

The second nitride region 20 includes Al_{y2}Ga_{1-y2}N (0<y2≤1). The second region 12 is between the first region 11 and the second nitride region 20. The second nitride region 20 may include crystals.

The first electrode 51 is electrically connected to the first region 11. The second electrode 52 is electrically connected to second nitride region 20.

A first direction D1 from the first region 11 to the second nitride region 20 is defined as a Z-axis direction. One direction perpendicular to the Z-axis direction is defined as an X-axis direction. A direction perpendicular to the Z-axis direction and the X-axis direction is defined as a Y-axis direction. The first region 11, the second region 12, and. the second nitride region 20 are, for example, along the X-Y plane.

FIG. 2 schematically illustrates the profile of the Al composition ratio a in the first region 11, the second region 12, and the second nitride region 20. FIG. 2 illustrates a case where these regions include AlαGa_{1-α}N (0≤α≤1). The horizontal axis in FIG. 2 is the position pZ along the first direction D1 (Z-axis direction). The vertical axis is the Al composition ratio α.

As illustrated in FIG. 2, the Al composition ratio x1 in the first region 11 decreases along the first direction D1 from the first region 11 to the second nitride region 20. The Al composition ratio x2 in the second region 12 decreases along the first direction D1. A first change rate of the composition ratio x1 with respect to a change in the position pZ along the first direction D1 is higher than a second change rate of the composition ratio x2 with respect to the change in the position pZ along the first direction D1. The first change rate corresponds to the slope of change in the composition ratio x1. The second change rate corresponds to the slope of change in the composition ratio x2.

With such a configuration, the first region 11 functions as, for example, a p⁺-layer. The second region 12 functions, for example, as a p⁻-layer. On the other hand, the second nitride region 20 may function as an n-layer. For example, the semiconductor device 110 functions as a pin diode.

For example, holes are generated due to a steep decrease in the Al composition ratio x1 in the first region 11. The concentration of holes in the first region 11 where the first change rate is high is higher than the concentration of holes in the second region 12 where the second change rate is low.

In the embodiment, the second region 12 may include substantially no Mg. Alternatively, the concentration of Mg in the second region 12 may be 1×10¹⁶/cm³ or less. By few impurities, it is easy to obtain high crystal quality in the second region 12. For example, it is easy to obtain a high breakdown voltage. For example, stable operation can be easily obtained. According to the embodiment, a semiconductor device whose characteristics can be improved can be provided. The first region 11 may include Mg. The concentration of Mg in the first region 11 may be, for example, not less than 1×10¹⁵/cm³ and not more than 1×10²⁰/cm³.

For example, the second region 12 is in contact with the first region 11 and the second nitride region 20.

The second nitride region 20 may include silicon. The concentration of silicon in the second nitride region 20 may be not less than 1×10¹⁸/cm³ and not more than 1×10²⁰/cm³.

The second nitride region 20 is of n-type and the first region 11 is of p-type. The first nitride region 10 and the second nitride region 20 function as diodes.

In the embodiment, the ratio of the first change rate to the second change rate may be 20 or more.

The composition ratio x1 may vary, for example, in a range not less than 0.1 and not more than 1. The composition ratio x2 may vary, for example, in a range not less than 0 and less than 0.3. The composition ratio y2 in the second nitride region 20 may be substantially constant. The composition ratio y2 may be, for example, not less than 0 and not more than 0.35, or the like.

As shown in FIG. 1, a thickness of the first region 11 along the first direction D1 is defined as a first region thickness t11. A thickness of the second region 12 along the first direction D1 is defined as a second region thickness t12. The first region thickness t11 is thinner than the second region thickness t12. By the second region 12 being thick, for example, a high breakdown voltage can be easily obtained.

In one example, the first region thickness t11 may be not less than 200 nm and not more than 1000 nm. The second region thickness t12 may be not less than 3000 nm and not more than 150000 nm.

A thickness of the second nitride region 20 along the first direction D1 is defined as a second nitride region thickness t20. The second nitride region thickness t20 is thinner than the second region thickness t12. The second nitride region thickness t20 may be, for example, not less than 20 nm and not more than 500 nm. The second nitride region thickness t20 may be thinner than the first region thickness t11.

In the example of the semiconductor device 110, the first region 11 includes a first partial region 11a and a second partial 15 region 11b. A second direction D2 from the second partial region 11b to the first partial region 11a crosses the first direction D1. The second direction D2 is, for example, the X-axis direction. The second region 12 is provided between the first partial region 11a and the second nitride region 20. The first electrode 51 overlaps the second partial region 11b in the first direction D1. In this 20 example, the first electrode 51 overlaps the second region 12 in the second direction D2.

As shown in FIG. 1, the semiconductor device 110 may further include a first electrode intermediate layer 51a. The first electrode intermediate layer 51a is provided between the second partial region 11b and the first electrode 51. The first electrode intermediate layer 51a includes at least one of Ga and Al, and nitrogen. The first electrode intermediate layer 51a includes Mg. The first electrode intermediate layer 51a may be a p-type GaN layer, a p-type AlGaN layer, a p-type AlN layer, or the like. Low resistance can be obtained.

As shown in FIG. 1, the semiconductor device 110 may include a base 18s and a third nitride region 30. In this example, the base 18s includes silicon. The third nitride region 30 includes Al_{z3}Ga_{1-z3}N (y2<z3≤1). The composition ratio z3 may be, for example, not less than 0.95 and not more than 1. The third nitride region 30 may be, for example, an AlN layer. The first nitride region 10 is provided between the base 18s and the second nitride region 20. The third nitride region 30 is between the base 18s and the first nitride region 10. By providing the third nitride region 30, the first nitride region 10 with high quality can be obtained.

By providing the first nitride region 10 with a gradient Al composition ratio, stress is alleviated, for example. For example, warping is suppressed.

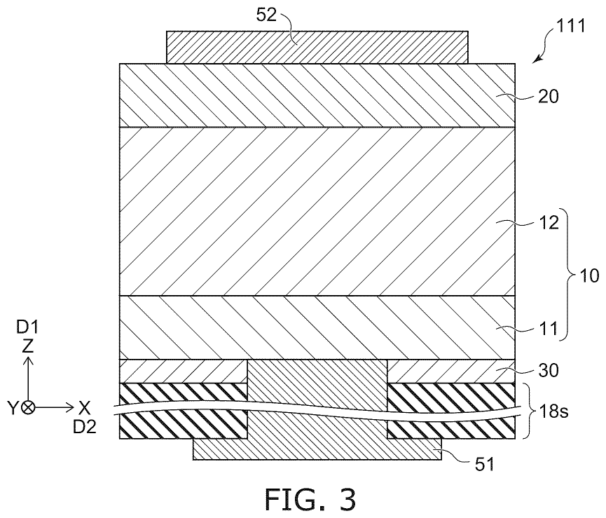

FIG. 3 is a schematic cross-sectional view illustrating a semiconductor device according to the first embodiment.

As shown in FIG. 3, in a semiconductor device 111 according to the embodiment, the configuration of the first electrode 51 is different from that in the semiconductor device 110. The configuration of the semiconductor device 111 except for this may be the same as the configuration of the semiconductor device 110.

The semiconductor device 111 includes the base 18s including silicon, and the third nitride region 30 including Al_{z3}Ga_{1-z3}N (y2<z3≤1). In the first direction D1, the base 18s is provided between at least a part of the first electrode 51 and the second electrode 52. The third nitride region 30 is provided between the base 18s and the second electrode 52. The first nitride region 10 is provided between the third nitride region 30 and the second electrode 52. The second nitride region 20 is provided between the first nitride region 10 and the second electrode 52. A direction from another part of the first electrode 51 to the base 18s crosses the first direction D1.

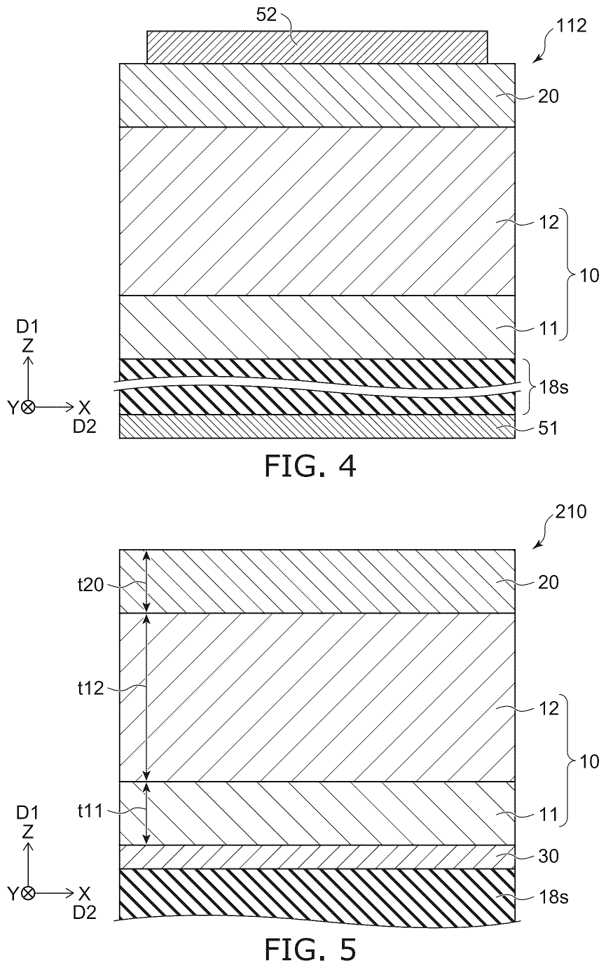

FIG. 4 is a schematic cross-sectional view illustrating a semiconductor device according to the first embodiment.

As shown in FIG. 4, in a semiconductor device 112 according to the embodiment, the configuration of the first electrode 51 is different from that in the semiconductor device 110. The configuration of the semiconductor device 112 except for this may be the same as the configuration of the semiconductor device 110.

As shown in FIG. 4, the semiconductor device 112 includes the base 18s being electrically conductive. The base 18s is provided between the first electrode 51 and the second electrode 52. The first nitride region 10 is provided between the base 18s and the second electrode 52. The second nitride region 20 is provided between the first nitride region 10 and the second electrode 52. The base 18s includes, for example, GaN. The third nitride region 30 may be omitted.

### Second Embodiment

FIG. 5 is a schematic cross-sectional view illustrating a wafer according to a second embodiment.

As shown in FIG. 5, a wafer 210 according to the embodiment includes the base 18s, the first nitride region 10, and the second nitride region 20. In the wafer 210, the configuration described in the first embodiment may be applied to the base 18s, the first nitride region 10, and the second nitride region 20.

The first nitride region 10 is provided between the base 18s and the second nitride region 20. The first nitride region 10 includes the first region 11 and the second region 12. The first region 11 includes Alₓ₁Ga₁₋ₓ₁N (0<x1≤1). The second region 12 includes Alₓ₂Ga₁₋ₓ₂N (0≤x2<x1). The second nitride region 20 includes Al_{y2}Ga_{1-y2}N (0<y2≤1). The second region 12 is provided between first region 11 and second nitride region 20.

In the wafer 210, the composition ratio x1 decreases along the first direction D1 from the first region 11 to the second nitride region 20 (see FIG. 2). The composition ratio x2 decreases along the first direction D1 (see FIG. 2). The first change rate of the composition ratio x1 with respect to the change in the position pZ along the first direction D1 is higher than the second change rate of the composition ratio x2 with respect to the change in the position pZ along the first direction D1.

For example, the first region 11 being of p-type is obtained. For example, the second region 12 may not include Mg. Alternatively, the Mg concentration in the second region 12 may be 1×10¹⁶/cm³ or less. For example, it is easy to obtain high crystal quality. For example, a wafer that can be applied to high voltage semiconductor devices can be provided. According to the embodiment, a wafer whose characteristics can be improved can be provided.

In the wafer 210, the second nitride region 20 may include silicon. The n-type characteristics can be stably obtained.

In the embodiment, information regarding the shape of the nitride region, etc. can be obtained, for example, by electron microscopic observation. Information regarding the composition and element concentration in the nitride region can be obtained by, for example, EDX (Energy Dispersive X-ray Spectroscopy) or SIMS (Secondary Ion Mass Spectrometry). Information regarding the composition in the nitride region may be obtained, for example, by reciprocal space mapping.

The embodiments may include the following Technical proposals:

### (Technical Proposal 1)

A semiconductor device, comprising:

a first nitride region including a first region and a second region, the first region including Alₓ₁Ga₁₋ₓ₁N (0<x1≤1), the second region including Alₓ₂Ga₁₋ₓ₂N (0≤x2<x1);

a second nitride region including Al_{y2}Ga_{1-y2}N (0<y2≤1), the second region being between the first region and the second nitride region;

a first electrode electrically connected to the first region; and

a second electrode electrically connected to the second nitride region,

a composition ratio x1 decreasing along a first direction from the first region to the second nitride region,

a composition ratio x2 decreasing along the first direction,

a first change rate of the composition ratio x1 with respect to a change in a position along the first direction being higher than a second change rate of the composition ratio x2 with respect to the change in the position along the first direction.

### (Technical Proposal 2)

The semiconductor device according to Technical proposal 1, wherein

a ratio of the first change rate to the second change rate is 20 or more.

### (Technical Proposal 3)

The semiconductor device according to Technical proposal 1 or 2, wherein

the second nitride region includes silicon.

### (Technical Proposal 4)

The semiconductor device according to Technical proposal 3, wherein

the second region is in contact with the first region and the second nitride region.

### (Technical Proposal 5)

The semiconductor device according to any one of Technical proposals 1-3, wherein

the second region does not include Mg, or

a concentration of Mg in the second region is 1×10¹⁶/cm³ or less.

### (Technical Proposal 6)

The semiconductor device according to any one of Technical proposals 1-5, wherein

a first region thickness of the first region along the first direction is thinner than a second region thickness of the second region along the first direction.

### (Technical Proposal 7)

The semiconductor device according to Technical proposal 6, wherein

the first region thickness is not less than 200 nm and not more than 1000 nm, and

the second region thickness is not less than 3000 nm and not more than 150000 nm.

### (Technical Proposal 8)

The semiconductor device according to Technical proposal 6 or 7, wherein

a second nitride region thickness of the second nitride region along the first direction is thinner than the second region thickness.

### (Technical Proposal 9)

The semiconductor device according to Technical proposal 8, wherein

the second nitride region thickness is not less than 20 nm and not more than 500 nm.

### (Technical Proposal 10)

The semiconductor device according to any one of Technical proposals 1-9, wherein

the first region includes a first partial region and a second partial region,

a second direction from the second partial region to the first partial region crosses the first direction,

the second region is between the first partial region and the second nitride region, and

the first electrode overlaps the second partial region in the first direction.

### (Technical Proposal 11)

The semiconductor device according to Technical proposal 10, further comprising:

a first electrode intermediate layer,

the first electrode intermediate layer being provided between the second partial region and the first electrode,

the first electrode intermediate layer including at least one of Ga and Al, and nitrogen, and

the first electrode intermediate layer includes Mg.

### (Technical Proposal 12)

The semiconductor device according to Technical proposal 10 or 11, wherein

the first electrode overlaps the second region in the second direction.

### (Technical Proposal 13)

The semiconductor device according to any one of Technical proposals 1-12, further comprising:

a base including silicon; and

a third nitride region including Al_{z3}Ga_{1-z3}N (y2<z3≤1),

the first nitride region being between the base and the second nitride region, and

the third nitride region being between the base and the first nitride region.

### (Technical Proposal 14)

The semiconductor device according to any one of Technical proposals 1-12, further comprising:

a base including silicon; and

a third nitride region including Al_{z3}Ga_{1-z3}N (y2<z3≤1),

the base being between at least a part of the first electrode and the second electrode in the first direction,

the third nitride region is between the base and the second electrode,

the first nitride region being between the third nitride region and the second electrode,

the second nitride region being between the first nitride region and the second electrode, and

a direction from another part of the first electrode to the base crossing the first direction.

### (Technical Proposal 15)

The semiconductor device according to any one of Technical proposals 1-9, further comprising:

a base being conductive,

the base being between the first electrode and the second electrode,

the first nitride region being between the base and the second electrode,

the second nitride region being between the first nitride region and the second electrode.

### (Technical Proposal 16)

The semiconductor device according to Technical proposal 15, wherein

the base includes GaN.

### (Technical Proposal 17)

The semiconductor device according to any one of Technical proposals 1-16, wherein

the first region is of a p-type,

the second nitride region is of a n-type, and

the first nitride region and the second nitride region are configured to function as a diode.

### (Technical Proposal 18)

A wafer, comprising:

a base;

a first nitride region; and

a second nitride region,

the first nitride region being between the base and the second nitride region,

the first nitride region including a first region and a second region,

the first region includes Alₓ₁Ga₁₋ₓ₁N (0<x1≤1),

the second region includes Alₓ₂Ga₁₋ₓ₂N (0≤x2<x1),

the second nitride region including Al_{y2}Ga_{1-y2}N (0<y2≤1),

the second region is between the first region and the second nitride region,

a composition ratio x1 decreasing along a first direction from the first region to the second nitride region,

a composition ratio x2 decreasing along the first direction,

a first change rate of the composition ratio x1 with respect to a change in a position along the first direction being higher than a second change rate of the composition ratio x2 with respect to the change in the position along the first direction.

### (Technical Proposal 19)

The wafer according to Technical proposal 18, wherein the second nitride region includes silicon.

### (Technical Proposal 20)

The wafer according to Technical proposal 18 or 19, wherein

the second region does not include Mg, or

a concentration of Mg in the second region is 1×10¹⁶/cm³ or less.

According to the embodiment, a semiconductor device and a wafer whose characteristics can be improved are provided.

In the present specification, the term “electrically connected state” includes a state in which a plurality of conductors are physically in contact and a current flows between the plurality of conductors. The “state of being electrically connected” includes a state in which another conductor is inserted between the plurality of conductors and a current flows between the plurality of conductors.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices and the wafers such as electrode, nitride regions, bases, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices and all wafers practicable by an appropriate design modification by one skilled in the art based on the semiconductor devices and the wafers described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first nitride region including a first region and a second region, the first region including Alₓ₁Ga₁₋ₓ₁N (0<x1≤1), the second region including Alₓ₂Ga₁₋ₓ₂N (0≤x2<x1);
a second nitride region including Al_{y2}Ga_{1-y2}N (0<y2≤1), the second region being between the first region and the second nitride region;
a first electrode electrically connected to the first region; and
a second electrode electrically connected to the second nitride region,
a composition ratio x1 decreasing along a first direction from the first region to the second nitride region,
a composition ratio x2 decreasing along the first direction,
a first change rate of the composition ratio x1 with respect to a change in a position along the first direction being higher than a second change rate of the composition ratio x2 with respect to the change in the position along the first direction.

2. The semiconductor device according to claim 1, wherein
a ratio of the first change rate to the second change rate is 20 or more.

3. The semiconductor device according to claim 1, wherein
the second nitride region includes silicon.

4. The semiconductor device according to claim 3, wherein
the second region is in contact with the first region and the second nitride region.

5. The semiconductor device according to claim 1, wherein
the second region does not include Mg, or
a concentration of Mg in the second region is 1×10¹⁶/cm³ or less.

6. The semiconductor device according to claim 1, wherein
a first region thickness of the first region along the first direction is thinner than a second region thickness of the second region along the first direction.

7. The semiconductor device according to claim 6, wherein
the first region thickness is not less than 200 nm and not more than 1000 nm, and
the second region thickness is not less than 3000 nm and not more than 150000 nm.

8. The semiconductor device according to claim 6, wherein
a second nitride region thickness of the second nitride region along the first direction is thinner than the second region thickness.

9. The semiconductor device according to claim 8, wherein
the second nitride region thickness is not less than 20 nm and not more than 500 nm.

10. The semiconductor device according to claim 1, wherein
the first region includes a first partial region and a second partial region,
a second direction from the second partial region to the first partial region crosses the first direction,
the second region is between the first partial region and the second nitride region, and
the first electrode overlaps the second partial region in the first direction.

11. The semiconductor device according to claim 10, further comprising:
a first electrode intermediate layer,
the first electrode intermediate layer being provided between the second partial region and the first electrode,
the first electrode intermediate layer including at least one of Ga and Al, and nitrogen, and
the first electrode intermediate layer includes Mg.

12. The semiconductor device according to claim 10, wherein
the first electrode overlaps the second region in the second direction.

13. The semiconductor device according to claim 1, further comprising:
a base including silicon; and
a third nitride region including Al_{z3}Ga_{1-z3}N (y2<z3≤1),
the first nitride region being between the base and the second nitride region, and
the third nitride region being between the base and the first nitride region.

14. The semiconductor device according to claim 1, further comprising:
a base including silicon; and
a third nitride region including Al_{z3}Ga_{1-z3}N (y2<z3≤1),
the base being between at least a part of the first electrode and the second electrode in the first direction,
the third nitride region is between the base and the second electrode,
the first nitride region being between the third nitride region and the second electrode,
the second nitride region being between the first nitride region and the second electrode, and
a direction from another part of the first electrode to the base crossing the first direction.

15. The semiconductor device according to claim 1, further comprising:
a base being conductive,
the base being between the first electrode and the second electrode,
the first nitride region being between the base and the second electrode,
the second nitride region being between the first nitride region and the second electrode.

16. The semiconductor device according to claim 15, wherein the base includes GaN.

17. The semiconductor device according to claim 1, wherein
the first region is of a p-type,
the second nitride region is of a n-type, and
the first nitride region and the second nitride region are configured to function as a diode.

18. A wafer, comprising:
a base;
a first nitride region; and
a second nitride region,
the first nitride region being between the base and the second nitride region,
the first nitride region including a first region and a second region,
the first region includes Alₓ₁Ga₁₋ₓ₁N (0<x1≤1),
the second region includes Alₓ₂Ga₁₋ₓ₂N (0≤x2<x1),
the second nitride region including Al_{y2}Ga_{1-y2}N (0<y2≤1),
the second region is between the first region and the second nitride region,
a composition ratio x1 decreasing along a first direction from the first region to the second nitride region,
a composition ratio x2 decreasing along the first direction,
a first change rate of the composition ratio x1 with respect to a change in a position along the first direction being higher than a second change rate of the composition ratio x2 with respect to the change in the position along the first direction.

19. The wafer according to claim 18, wherein
the second nitride region includes silicon.

20. The wafer according to claim 18, wherein
the second region does not include Mg, or
a concentration of Mg in the second region is 1×10¹⁶/cm³ or less.
